(19) United States
(12) Patent Application Publication
(10) Pub. No.: US 2009/0237076 A1
(43) Pub. Date: Sep. 24, 2009

(54) MAGNETIC RESONANCE IMAGING APPARATUS, A METHOD AND A COMPUTER PROGRAM FOR COMPENSATION OF A FIELD DRIFT OF THE MAIN MAGNET

(75) Inventor: Cornelis Leonardus Gerardus Ham, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., Eindhoven (NL)

(21) Appl. No.: 11/720,934

(22) PCT Filed: Dec. 9, 2005
(86) PCT No.: PCT/IB05/54149

§ 371 Date: Jun. 6, 2007

(30) Foreign Application Priority Data
Dec. 14, 2004 (EP) 04106534.3

(51) Int. Cl. G01R 33/3873; G01R 33/38

(52) U.S. Cl. 324/307; 324/322

(57) ABSTRACT

In accordance with the technical measure of the invention in order to counteract the positive feedback between the superconducting magnet and the shim iron a pair of superconducting shunts (37, 38) is provided with a region of overlap (38a-37b) substantially matching the position of the shim iron (20) within the magnet system (40a). For the shim iron (20) being positioned below coil segments (31c, 31d) the region of overlap must include coil segments (31c, 31d). In this way a first superconducting shunt (37), having its connection points (37a, 37b), and the second superconducting shunt (38), having its connection points (38a, 38b), overlap in a region encompassing the coil segments (31c, 31d) and, thus the shim iron (20). The superconducting shunts (37, 38) are provided with operatable switches (not shown for clarity), which must be kept open during the ramp-up of the magnet. After the magnet has reached the persistent mode, the operatable switches must be kept closed for the whole operational time of the magnetic resonance imaging apparatus. Preferably, the operatable switches are implemented as per se known thermal switches connectable to a suitable heater.

The invention relates to a magnetic resonance imaging apparatus comprising:

a main magnet for generating a substantially homogenous magnetic field in an imaging volume, said main magnet comprising a plurality of electrically connected coil sections arranged in an electric circuit, whereby in operation said coil sections are arranged to generate respective magnetic fields;

a magnetizable body arranged in a magnetic field of a coil section.

The invention further relates to a method of reducing a field drift in a magnetic resonance imaging apparatus comprising a main magnet for generating a substantially homogenous magnetic field in an imaging volume, said main magnet comprising a plurality of electrically connected coil sections arranged in an electric circuit and conceived to generate respective magnetic fields in operation, a magnetizable body arranged in a magnetic field of a coil section.

The invention still further relates to a computer program for reducing a field drift in a magnetic resonance imaging apparatus.

Magnetic resonance apparata are known per se. An embodiment of a magnetic resonance apparatus as is set forth in the opening paragraph is known from US 2004/0169513 A1. A main magnetic field is generated by means of a main magnet in an imaging volume conceived to receive an object, notably, a patient to be imaged. In order to select a region to be imaged in the relevant object, one or more gradient coils are provided so as to superpose magnetic field gradients on the main magnetic field. By order of convention, the gradient field coils produce linear variations of the main magnetic field along the x, the y and the z axis of a Cartesian co-ordinate system. In order to achieve resonance for nuclei in a selected body region to be imaged, there are provided one or more RF coils which are arranged to receive signals emanating from the object subjected to the magnetic resonance imaging.

An important condition imposed on this type of imaging apparata is that in operation the main magnetic field should be as uniform and constant as possible during an excitation and acquisition of imaging data. Fluctuations in the main magnetic field have a negative effect on the imaging accuracy of the magnetic resonance apparatus. It is widely acknowledged that in order to achieve a homogeneous main field use is made of a passive shim system, conventionally called a shim iron, which is used for shimming the main magnet. It is also recognized that during operation of the magnetic resonance imaging apparatus the temperature of the shim iron changes leading to a change in the amount of field lines through the shim iron. Therefore, a change in the temperature of the shim iron will perturb the main field, which is unacceptable.

In the known document an arrangement is proposed to compensate against such variations in the main field due to temperature-dependent behavior of the shim iron. In particular, the known arrangement is used to determine a quantity which is characteristic of the temperature-dependent magnetic properties of the shim iron and to determine a compensation signal to be applied to compensation means on basis of said quantity. The compensation means of the known arrangement comprises an auxiliary coil which must be arranged in the main magnet. The compensation signal is determined based on the effect of the field drift on the field strength of the main magnetic field, calculated for a given quantity and configuration of the shim iron.

It is a disadvantage of the known magnetic resonance imaging apparatus that a complicated arrangement is required in order to compensate for a temperature drift of the magnetizable body, whereby the accuracy and reliability of the arrangement is dependent on the knowledge of the system characteristics of the magnetic resonance apparatus as a whole.

It is an object of the invention to provide a magnetic resonance imaging apparatus whereby the field drift of the main magnet due to temperature-dependent behavior of the magnetizable body is reliably compensated using simple means.

To this end the magnetic resonance imaging apparatus according to the invention is characterized by that it comprises a pair of electric shunts, bridging respective parts of the electric circuit, said pair of shunts comprising a first shunt and a second shunt, whereby the first shunt is connected between a first connection point and a second connection point in the electric circuit and the second shunt is connected between a third connection point and a fourth connection point in the electric circuit, each electric shunt comprising an operatable switch, said pair of electric shunts being arranged in a mutually interleaved order comprising a region of overlap between the third connection point and the second connection point, whereby said region of overlap is arranged to cover at least a portion of a coil section, substantially matching a position of the magnetizable body.

The technical measure of the invention is based on the recognition of the fact that the main magnet, notably a superconducting magnet has the property to keep the enclosed magnetic flux at a constant value. A part of the magnetizable body, constituting the passive shim system, notably a shim iron or a booster, is not enclosed by a coil section. A change in the enclosed magnetic flux will be compensated by the superconducting magnet by changing its current to keep the total enclosed magnetic flux constant. Therefore, the field drift of the magnetizable body positioned in a direct vicinity of the coil section will be amplified by the magnet, thus there exists a positive feedback.

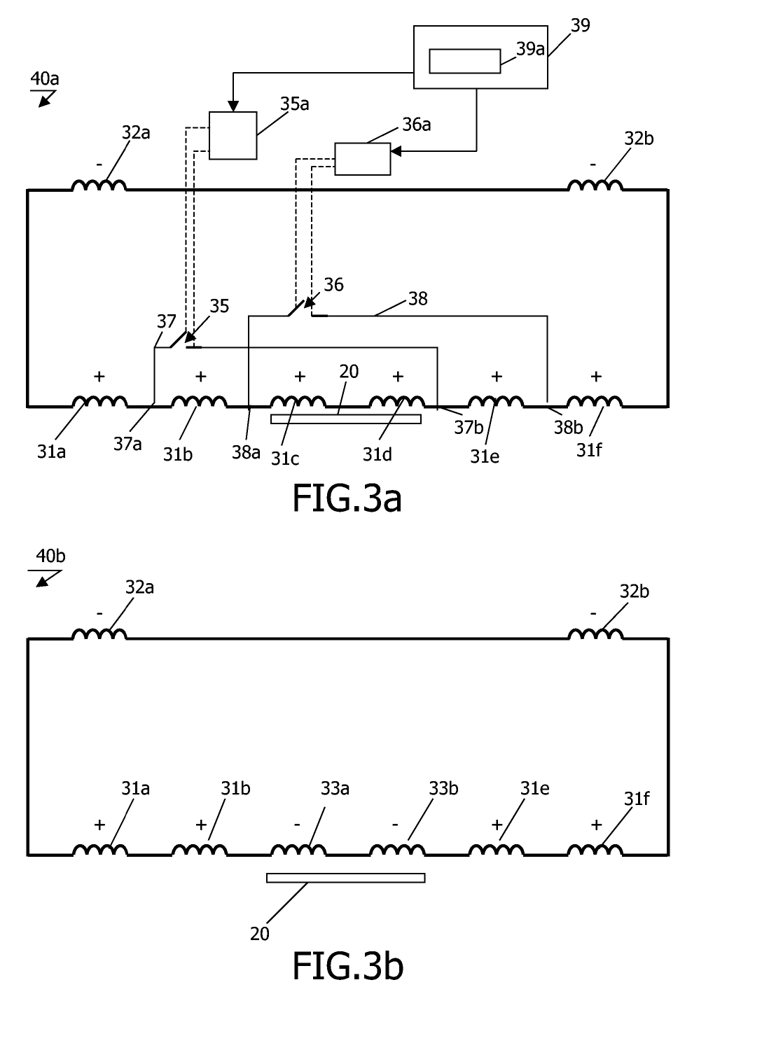

The technical measure of the invention reverses the positive feed-back of the main magnet and therefore compensates for the field drift of the magnetizable body. Indeed, when the region of overlap is positioned substantially matching the position of the magnetizing body with respect to at least a portion of a coil section, the portion of the coil section falling within the region of overlap will change its polarity leading to an establishment of a negative feedback, thus compensating for the field drift in the magnetizable body. It must be noticed that it is essential that the electric shunts have some resistance, otherwise an unacceptable amount of electric current would flow through the shunt instead of through the coil. The wire itself, suitable for the shunt, might be of a conventional type. Alternatively, only the connection between superconducting wires can be implemented as a piece of a conventional wire. The time constant of the shunt is a combination of the resistance of the shunt and a self-inductance of the set of coil sections falling within the region of overlap. The electric shunt will have very low resistance at a temperature of 4 Kelvin, leading to a very long time constant, typically >24 hours. The controllable switch is used to increase the resistance of the shunt yielding the time constant of about one minute. Further details of this embodiment will be discussed with reference to FIGS. 3a and 3b. Also, due to its simplicity the technical measure of the invention hardly requires any maintenance, calibration and tuning.

It must be noted that a mere arrangement of electric shunts in the circuit of the coil sections of the main magnet is known per se. For example, from U.S. Pat. No. 5,426,366 it is known that a pair of shunts may be arranged in the superconducting coil system for purposes of improving shielding against external field fluctuations. The teaching of U.S. Pat. No. 5,426,366 does not address the problem of a field drift of the main field due to temperature variation of the magnetizable bodies positioned in a direct vicinity of the main magnet. Also, in accordance with this teaching a sole shunt may be provided which bridges the magnet system and is connected between at least an end of the coil system. Optionally, a second shunt may be connected within the coil system of the main magnet, whereby the connection points of this shunt are connected to the first end and the second end of the coil system of the main magnet. Therefore, it is concluded that the technical measure of U.S. Pat. No. 5,426,366 does not disclose a provision of paired shunts, which are interleaved. The known shunts do have an area of overlap, however, even if it is positioned accidentally above the position of the shim iron, in its operation it will never reach the negative feedback effect which constitutes the core insight of present invention.

Secondly, U.S. Pat. No. 6,777,938 B2 describes an arrangement of superconducting shunts within the coil system of the main magnet of the magnetic resonance apparatus. According to U.S. Pat. No. 6,777,938 B2 a plurality of superconductive shunts may be provided over a number of disjoint coil sections, said superconductive shunts being provided with switches which are operatable by activating means to separately short-circuit disjoint coil sections during operation of the magnetic resonance imaging apparatus. In accordance with this technical measure a drift of the operational current due to residual resistance may be counteracted. Also with regard to this disclosure, it must be concluded that it does not reach the solution of present invention, as even when two switches are closed in operation, which are accidentally positioned above the shim iron, the thus formed shunts will not be ordered in the interleaved fashion and, thus, will not have the sought negative feed-back effect on the field drift caused by the temperature-dependent behavior of the shim iron.

Thirdly, US 2002/0171520 discloses a shunt system in the main magnet of a magnetic resonance imaging apparatus comprising at least two shunts, whereby the shunts are ordered in the overlapping, yet not interleaved way. In conformity with the above arguments, also in this case it is concluded that such an arrangement will not induce a negative feed-back of the field drift caused by the temperature-dependent behavior of the shim iron.

In an embodiment of the magnetic resonance apparatus according to the invention the third connection point and the second connection point are arranged between respective coil sections.

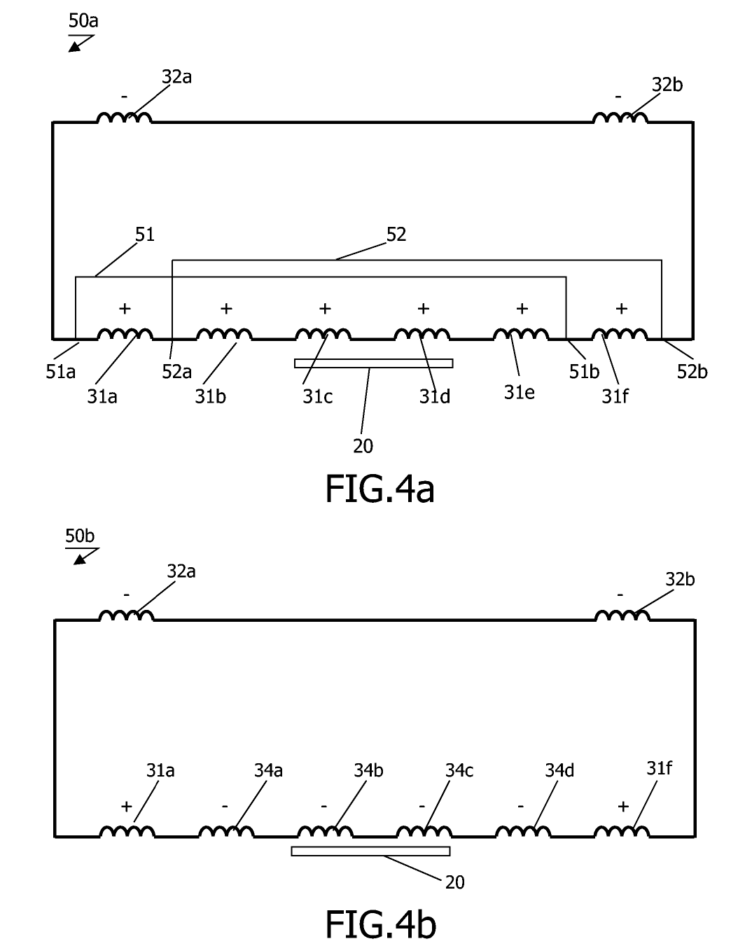

It is understood that in most cases due to a limited dimension of the magnetizable body, notably the shim iron, which is generally in the range of 1.0 to 1.2 m, it will be sufficient to encompass one or two coil sections positioned above the shim iron. For optimum operation, however, it is preferable to include more coil sections in the region of overlap, see FIGS. 4a and 4b.

In a further embodiment of the magnetic resonance apparatus according to the invention the third connection point and the second connection point are arranged on respective coil sections.

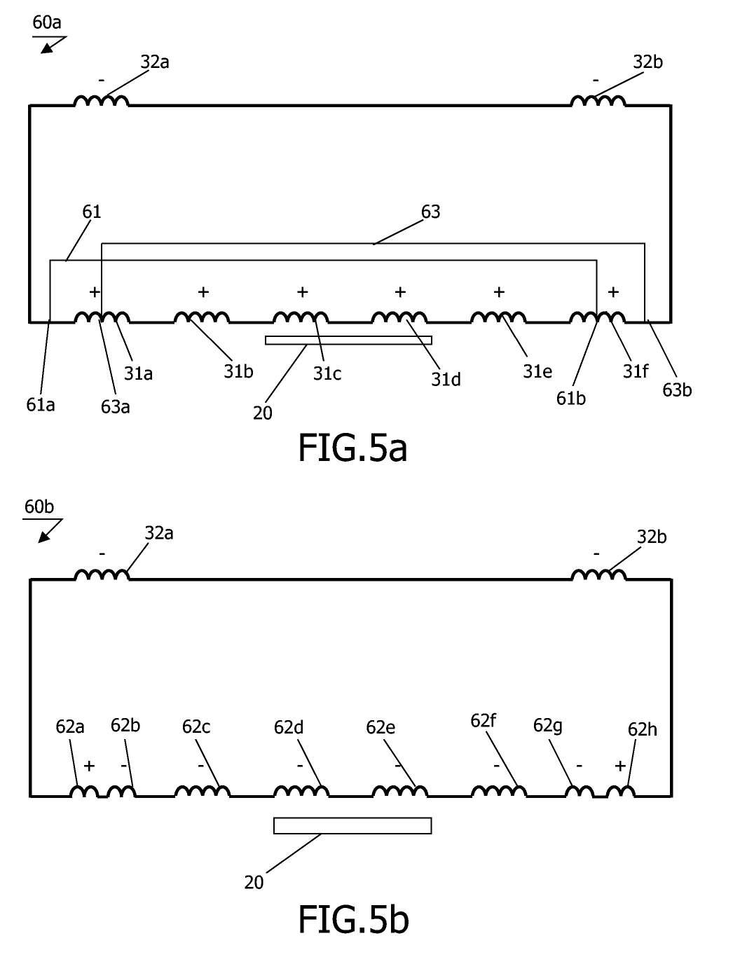

Preferably, the third connection point and the second connection point are arranged midway the respective coil sections, for symmetry purposes. This arrangement allows compensating for a change in flux, which is not covered by entire coil sections. These embodiments are schematically illustrated on FIGS. 5a and 5b. It is mentioned, however, that the third and the second connection point could be placed anywhere inside a respective coil section, not necessarily at their respective midpoints.

It is noted that a great plurality of possible connections of the respective shunts are possible without departing the scope of invention.

The method according to the invention comprises the step of:

arranging a pair of electric shunts, bridging respective parts of the electric circuit, said pair comprising a first shunt and a second shunt, whereby the first shunt is connected between a first connection point and a second connection point in the electric circuit and the second shunt is connected between a third connection point and a fourth connection point in the electric circuit, each electric shunt comprising an operatable switch, said pair of electric shunts being arranged in a mutually interleaved order comprising a region of overlap between the third connection point and the second connection point, whereby said region of overlap is arranged to cover at least a portion of a coil section, substantially matching a position of the magnetizable body.

Preferably, the method according to the invention comprises the further steps of:

opening the operatable switches during a ramp-up of the main magnet;

closing the operatable switches during operation of the magnetic resonance imaging apparatus.

Prior to initiation of the shunt system in accordance to the invention, the operatable switches must be kept open during a ramp-up of the main magnet allowing the coil sections to acquire working polarity. In the persistent mode the operatable switches are to be closed so that the automatic field-drift compensating system in accordance with the invention is created. Preferably, the operatable switches are implemented as thermal switches connected to a suitable heater. Such switches are known per se in the art, for example from US 2002/0171520.

Still preferably, in the method according to the invention for the operatable switches computer controlled switches are selected, the method further comprising the steps of:

closing the operatable switches before a data acquisition step using a computer command;

performing the data acquisition step.

This particular embodiment is preferable as it saves power due to the fact that the energy is supplied to the heaters only when the magnetic resonance apparatus enters a data acquisition mode. Preferably, an operational mode of the heater and, thus, of the switches, is controlled by a processor, which is controlled by a computer program in accordance with Claim 9 or Claim 10. The computer program may be implemented as a part of a scan initiation routine, whereby a command is envisaged to increase a power supply to the heaters in order to close the operatable switches and to set the time constant of the shunts to a value of about one minute. After the operatable switches are thus closed, the computer program sets the magnetic resonance imaging apparatus ready for implementing a suitable data acquisition sequence.

These and other aspects of the invention will be discussed in further details with reference to figures, whereby like reference signs represent like items.

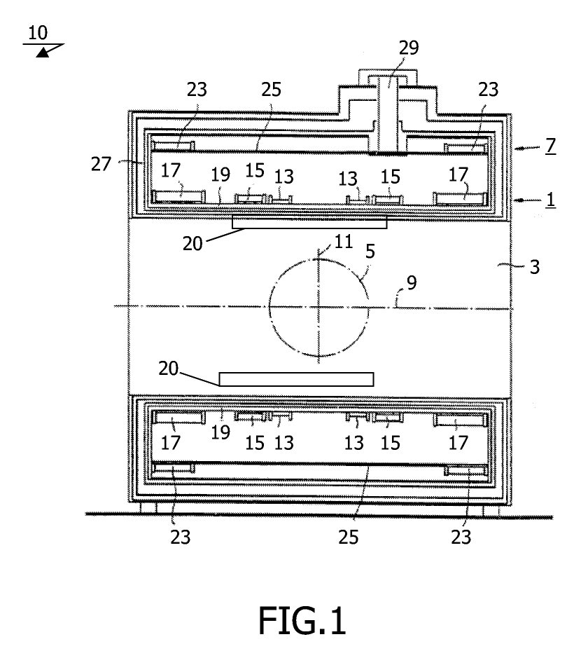

FIG. 1 shows in a schematic way an embodiment of a magnetic resonance apparatus according to the invention.

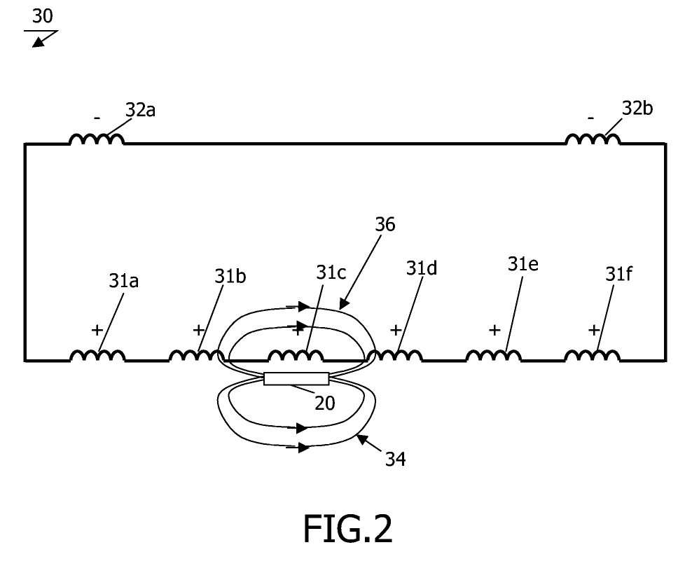

FIG. 2 shows in a schematic way an equivalent electric scheme of the main magnet provided with a shim iron.

FIG. 3a shows in a schematic way an equivalent electric circuit of the main magnet provided with a pair of electric shunts in accordance with the invention.

FIG. 3b shows in a schematic way an effect of the field change on the coil sections falling within the region of overlap.

FIG. 4a shows in a schematic way an equivalent electric circuit of the main magnet provided with a pair of electric shunts in accordance with the invention with an elongated region of overlap.

FIG. 4b shows in a schematic way an effect of the field change on the coil sections falling within the elongated region of overlap.

FIG. 5a shows in a schematic way an equivalent electric circuit of the main magnet provided with a pair of electric shunts, whereby connection points are located on the coil sections.

FIG. 5b shows in a schematic way an effect of the field change on the coil sections falling within the corresponding region of overlap.

FIG. 1 shows in a schematic way an embodiment of a magnetic resonance apparatus according to the invention. In this embodiment the magnetic resonance imaging apparatus 10 comprises an approximately cylindrical electromagnetic inner coil system 1 comprising a plurality of coil segments (not shown), which encloses a receiving space 3 which usually also has a cylindrical central part and an approximately spherical central part, which acts as a measuring volume 5 and is denoted by dashed line. It must be noted that however for illustration purposes a bore-type magnetic resonance imaging apparatus is shown, the invention may as well be practice in so-called open systems where the inner coil system 1 is not cylindrically shaped. A patient (not shown) can be introduced into the receiving space 3, so that a part of the patient to be imaged is localized in the measuring volume 5. The inner coil system 1 is enclosed by an outer coil system 7. The two coil systems 1, 7 and the receiving space 3 are rotationally symmetrical relative to a central axis 9, denoted by a dot-dash line 11.

The inner coil system 1 of the present embodiment comprises a pair of inner coils 13 a pair of central coils 15, and a pair of outer coils 17. Said coil pairs 13, 15, 17 are symmetrically situated relative to a symmetry plane 11, i.e. the coils of the same pair which are situated to both sides of the symmetry plane comprise same numbers of turns and are the mirror image of one another in respect of shape and distribution of the turns. In order to homogenize the magnetic field produced by the inner coil system 1, a passive shim system comprising a magnetizable material, known in the art as shim iron 20 is introduced. It is noted that the position of the shim iron with respect to the inner coil system 1 is exaggerated for clarity reasons. Also, usually the shim iron consists of a set of pieces of iron, or any other suitable magnetizable material, set pieces being set on rails. These rails are mounted to the inner bore of the magnet. Alternatively, the pieces of shim iron 20 may be integrated into the gradient coils. In both cases the shim iron 20 is located in a direct vicinity to the coil sections 13, 15, 17 where in operation of the magnetic resonance imaging apparatus it is positioned in a magnetic field generated by a respective coil portion. For the simplicity reasons the shim iron 20 is shown as a single block with exaggerated dimensions. Also the distance between coil sections 13, 15, 17 and the magnetizable body 20 is exaggerated. A homogeneity booster, which is not shown for clarity reasons, is usually located in a gradient coil or in a body transmit and receive coil. The technical measure of the invention is applicable to the homogeneity booster as well in order to counteract a field drift caused by a temperature change of a magnetizable material constituting the homogeneity booster. The coils 13, 15, 17 of the inner coil system 1 are provided on a first common support 19. The outer coil system 7 comprises a pair of coils 23 which are also symmetrical with respect to the symmetry plane 11. The coils 23 of the outer coil system are accommodated on a second common support 25.

The two coil systems 1, 7 are accommodated in a Dewar vessel 27 which can be filled with a suitable cooling liquid, for example liquid helium, via an inlet 29. The coils constituting the coil system 1, 7 are made of a material which is superconducting at the temperature of the cooling liquid.

FIG. 2 shows in a schematic way an equivalent electric scheme of the main magnet provided with a shim iron. The equivalent electric scheme 30 of the inner coil system can be represented by a series connection of a plurality of inductive coils 32a, 32b, 31, 31b, 31c, 31d, 31e, 31f, whereby coil segments in a vicinity of the shim iron 20 have a positive field contribution. The shim iron 20 is placed inside the magnet coils 30 and can change its temperature, for example due to a drift in the ambient temperature and/or due to the switching of the gradient coils of the magnetic resonance imaging apparatus. As a result the amount of the field lines 34, 36 through the shim iron 20 changes leading to a change in the magnetic field in the imaging volume. The superconductive magnet has a property to keep the enclosed flux at a constant value. Thus when the flux through the shim iron 20 changes due to a temperature drift of the shim iron 20 the superconducting magnet will change its current to keep the total enclosed flux constant. Generally, the shim iron has a negative contribution to the field, thus when a temperature increases the field will increase also. Thus, the interaction between the superconducting magnet and the shim iron has a direct effect, amplifying the field drift of the shim iron. This effect is counteracted by the technical measure of the invention, as is set forth with respect to a number of embodiments, shown in FIGS. 3a-5b.

FIG. 3a shows in a schematic way an equivalent electric circuit of the main magnet provided with a pair of electric shunts in accordance with the invention. The shunt is located inside the cryostat, which is the container of the superconducting coil sections. In accordance with the technical measure of the invention in order to counteract the positive feedback between the superconducting magnet and the shim iron a pair of interleaved electric shunts 37, 38 is provided with a region of overlap 38a-37b substantially matching the position of the shim iron 20 within the magnet system 40a. Let us assume that the shim iron 20 is positioned below coil segments 31c, 31d. In this way a first electric shunt 37, having its connection points 37a, 37b, and the second electric shunt 38, having its connection points 38a, 38b, overlap in a region encompassing the coil segments 31c, 31d and, thus the shim iron 20. The electric shunts 37, 38 are provided with operatable switches 35, 36, which must be kept open during the ramp-up of the magnet. After the magnet has reached the persistent mode, the operatable switches 35, 36 can be kept closed for the whole operational time of the magnetic resonance imaging apparatus. Preferably, the operatable switches are implemented as per se known thermal switches connectable to a suitable heater 35a, 36a. Preferably, the heaters 35a, 36a are computer controlled by means of a computer program 39a arranged to operate a processor 39. In this case, as an alternative embodiment, it is preferable that the computer program 39a comprises instructions to increase the heat directed to the operatable switches 35, 36 so that they are closed before a data acquisition sequence of the magnetic resonance apparatus. It is possible that the computer program 39a is implemented as a part of a scan initiation sequence. Preferably, the time constant of the superconducting shunts 37, 38 is set by design to a different value than the conventional shunt circuit, as is used for external field changes. Those external field changes have a time characteristic of the order of 1-10 seconds (e.g. caused by passing cars). The time constant of the shunt circuits 37, 38 should be longer than this time, e.g 30 seconds. The typical change rate of the internal field changes (e.g. temperature change of iron) is of the order of 3-30 minutes. The circuit with the paired shortcuts should have a time constant longer than this time, e.g. 60 minutes. FIG. 3b shows in a schematic way an effect of the field change on the coil sections falling within the region of overlap. It is seen that due to the region of overlap the coil segments 33a, 33b have changed their polarity with respect to the original value, which effectively counteracts the field change induced by the shim iron 20 due to the temperature drift thereof.

FIG. 4a shows in a schematic way an equivalent electric circuit of the main magnet provided with a pair of electric shunts in accordance with the invention with an elongated region of overlap. As was pointed out earlier, the embodiment of FIG. 3a works well for shim irons situated directly under the coil segments 31c, 31d. In practice, shim irons generally take a longer part of the magnet that those two mid-segments, their length being typically in the range of 1.0 to 1.2 m. For optimum operation it is preferable to include more coil segments in the region of overlap 38a-37b for a better compensation of the field drift of the shim iron 20. In the embodiment of FIG. 4a four coil segments are enclosed by the region of overlap 52a-51b. Other technical details, including operatable switches, heaters and computer program are kept similar to those discussed with reference to FIG. 3b. As a consequence, four coil segments falling within the region of overlap 52a-51b change their polarity, see FIG. 4b, which shows in a schematic way an effect of the field change on the coil sections falling within the elongated region of overlap.

FIG. 5a shows in a schematic way an equivalent electric circuit of the main magnet provided with a pair of electric shunts, whereby connection points are located on the coil sections, other technical details being the same as for FIG. 3a. In this embodiment the connection points defining the region of overlap 63a and 61b are located taps halfway respective coil sections 31a, 31f. As a result, the coil section falling within the region of overlap 63a-61b change their polarity with respect to the original value, see FIG. 5b which shows in a schematic way an effect of the field change on the coil sections falling within the corresponding region of overlap.

1. A magnetic resonance imaging apparatus comprising:
a superconducting main magnet for generating a substantially homogenous magnetic field in an imaging volume, said main magnet comprising a plurality of electrically connected coil sections arranged in an electric circuits whereby in operation said coil sections are arranged to generate respective magnetic fields;
a magnetizable body arranged in a magnetic field of a coil section, wherein the magnetic resonance imaging apparatus further comprises:
a pair of electric shunts, bridging respective parts of the electric circuit, said pair of shunts comprising a first shunt and a second shunt, whereby the first shunt is connected between a first connection point and a second connection point in the electric circuit and the second shunt is connected between a third connection point and a fourth connection point in the electric circuit, each electric shunt comprising an operatable switch, said pair of electric shunts being arranged in a mutually interleaved order comprising a region of overlap between the third connection point and the second connection point, whereby said region of overlap is arranged to cover at least a portion of a coil section, substantially matching a position of the magnetizable body.

2. A magnetic resonance imaging apparatus according to claim 1, wherein the third connection point and the second connection point are arranged between respective coil sections.

3. A magnetic resonance imaging apparatus according to claim 1, wherein the third connection point and the second connection point are arranged on respective coil sections.

4. A magnetic resonance imaging apparatus according to claim 1, wherein the operatable switches being thermal switches connectable to a heater power supply.

5. A magnetic resonance imaging apparatus according to claim 4, wherein the operatable switches are computer controlled.

6. A method of reducing a field drift in a magnetic resonance imaging apparatus comprising a main magnet for generating a substantially homogenous magnetic field in an imaging volume, said main magnet comprising a plurality of electrically connected coil sections arranged in an electric circuit and conceived to generate respective magnetic fields in operation, a magnetizable body arranged in a magnetic field of a coil section, said method comprising the step of:
arranging a pair of electric shunts, bridging respective parts of the electric circuit, said pair of shunts comprising a first shunt and a second shunt, whereby the first shunt is connected between a first connection point and a second connection point in the electric circuit and the second shunt is connected between a third connection point and a fourth connection point in the electric circuit, each electric shunt comprising an operatable switch, said pair of electric shunts being arranged in a mutually interleaved order comprising a region of overlap between the third connection point and the second connection point, whereby said region of overlap is arranged to cover at least a portion of a coil sections, substantially matching a position of the magnetizable body.

7. A method according to claim 6, whereby said method further comprises the following steps:
opening the operatable switches during a ramp-up of the main magnet;
closing the operatable switches during operation of the magnetic resonance imaging apparatus.

8. A method according to claim 7, whereby for the operatable switches computer controlled switches are selected, the method further comprising the steps of:
closing the operatable switches before a data acquisition step using a computer command;
performing the data acquisition step.

9. A computer program for reducing a field drift in a magnetic resonance imaging apparatus comprising:
a main magnet with a set of coils, arranged in an electric circuit, at least a pair of interleaved electric shunts with an overlapping region conceived to cover at least a portion of the said coils, each pair of electric hunts having an operable switch;
a magnetizable body arranged in a magnetic field of the coils;
said computer program comprising instructions for causing a processor to carry the following steps:
closing the operable switch before a data acquisitions step.

10. A computer program according to claim 9, whereby the computer program further comprises an instruction for a processor to carry out the step of performing a data acquisition.
